(19) United States
(12) Patent Application Publication
(10) Pub. No.: US 2026/0274609 A1
(43) Pub. Date: Sep. 17, 2026

(54) Cable Slack Storage Panels

(71) Applicant: Go!Foton Holdings, Inc., Somerset, NJ (US)

(72) Inventors: Kenichiro Takeuchi, North Brunswick, NJ (US); Alla Shtabnaya, Hillsborough, NJ (US); David Zhi Chen, Dallas, TX (US); Brian Berdan, Montgomery, MN (US); Haruki Nakagawa, Milford, NJ (US)

(73) Assignee: Go!Foton Holdings, Inc., Somerset, NJ (US)

(21) Appl. No.: 19/564,899

(22) Filed: Mar. 12, 2026

Related U.S. Application Data
(60) Provisional application No. 63/771,755, filed on Mar. 14, 2025.
(60) Provisional application No. 63/793,174, filed on Apr. 23, 2025.

(51) Int. Cl. B65H 75/36; B65H 57/02; B65H 75/44

(52) U.S. Cl. CPC B65H 75/364; B65H 57/02; B65H 75/4402; B65H 75/4492; B65H 2404/7431; B65H 2601/25; B65H 2701/34

(57) ABSTRACT

A panel having a drawer and a chassis (i.e., frame). The drawer having a front portion and a base portion. The base portion having a first row of posts, a second row of posts, and a third row of posts and separator walls defining cable channels configured to accommodate a plurality of slack cable lines. The chassis defining an opening that is configured to receive the drawer and two or more cable guides disposed on opposite sides of the opening. The cable guides are configured to bundle together the plurality of slack cable lines.

### CROSS-REFERENCE TO RELATED APPLICATIONS

The present application claims the benefit of the filing date of U.S. Provisional Patent Application Nos. 63/771,755 filed Mar. 14, 2025, and 63/793,174 filed Apr. 23, 2025, the disclosure of which is incorporated herein by reference in its entirety.

### BACKGROUND

Cable slack is typically needed in hardware network systems to provide ready-to-use cable length that may be utilized when network connections are rearranged, extended to external devices, or the like. Cable slack is often stored in racks along with panels (e.g., patch panels) that house connection ports. In such configurations, connections between panels or external devices may be provided through the use of slack in a cable line that is long enough to establish the connection. For example, on occasion it may be necessary to connect a patch panel to a distant device, such as another patch panel that is mounted in a remotely positioned rack. Storing enough slack to establish these types of connections may become unwieldly, and the slack may be tangled if not properly stored. Thus, there is a need for devices capable of storing lengths of excess cable sufficient to provide for any remote connections that may become necessary, and thus a need to manage such storage.

### BRIEF SUMMARY

It has been recognized that there is a need to efficiently store excess cable (i.e., cable slack) that is readily available and accessible for hard-wired connection between rack-mounted units and distant devices. It has been further recognized that hardware networks need to include excess cable that could be used to establish hard-wired connections between a rack-mounted device and a multiple of distant devices for future network expansion. In view of the need to efficiently provide excess cable for hard-wired connection of rack-mounted units to multiple distant devices, the technology described in this disclosure is provided.

In accordance with an aspect of the presently disclosed technology, a cable storage panel is provided, the cable storage panel including a drawer having a height dimension, a width dimension, and a length dimension, the drawer having a front portion and a bottom or base portion connected to the front portion. The drawer configured to accommodate cable slack for one or more lines of cable within slack storage components and cable guides, each cable guide configured to route one or more cables from a cable inlet to a cable outlet, and the slack storage component or components may be disposed between the inlet and outlet.

In another aspect, the present disclosure relates to a cable storage panel that may include a chassis and a drawer having a height dimension, a width dimension, and a length dimension. The drawer may have a front portion and a base portion. The base portion may have an elongated post and curved separators defining cable channels configured to accommodate a plurality of slack cable lines. The chassis may define an opening that is configured to receive the drawer and two or more cable guides disposed on opposite sides of the opening. The cable guides may be configured to bundle together the plurality of slack cable lines. The elongated post may be located proximate to a center of the base portion. The panel may further comprise a first side post and a second side post disposed proximate a first side of the base portion and a second side of the base portion, respectively. Some of the curved separators may be disposed between the elongated post and the first and second side posts. One of the first and second side posts may be spaced between 2 and 12 inches away from the front portion of the drawer. The curved separators may be concentrically disposed around the elongated post. The curved separators may define an inner ring and an outer ring centered around the elongated post. The inner and outer rings may include cable slots.

In some instances, the panel may further comprise an attachment arm having one end attached to the base portion and the other end defining an aperture configured to receive and attach to cable lines of the plurality of slack cable lines. In other instances, the panel may further comprise a back portion attached to the base portion opposite from the front portion. Yet in other instances, the panel may further comprise a ledge extending from at least one separator of the curved separators, wherein the ledge extends over a cable channel of the cable channels. In some other instances, the panel may further comprise an inner channel, a middle channel, and an outer channel of the cable channels. The outer channel may extend between an outer separator of the curved separators and the first and second side posts. The inner channer may extend between an inner separator of the curved separators and the elongated post.

In accordance with another aspect, the present disclosure relates to a cable storage panel including a chassis, a first cable spool, a second cable spool, and a drawer having a height dimension, a width dimension, and a length dimension. The drawer may have a front portion and a base portion. The first cable spool may be rotatably connected to the base portion and configured to accommodate slack from a plurality of cable lines. The first cable spool may include a flange. The second cable spool may be rotatably connected to the base portion and configured to accommodate slack from the plurality of cable lines. The second cable spool may include a flange parallel to the flange of the first cable spool. The chassis may define an opening that is configured to receive the drawer and two or more cable guides disposed on opposite sides of the opening. The first cable spool may be disposed closer to the front portion than the second cable spool. The first cable spool may be spaced between 6 and 24 inches away from each other. The first cable spool may be configured to rotate counter clockwise when the drawer is pulled from a closed position to an opened position. The first and second cable spools may be configured to rotate simultaneously when the drawer is pulled from the chassis. The second cable spool may be configured to rotate clockwise when removed from the drawer.

In some instances, the panel may further comprise a first arm having a first end attached to the chassis and a second end attached to the first cable spool. In other instances, the panel may further comprise a second arm having a first end attached to the chassis and a second end attached to the second cable spool. One of the second ends of the first and second arms may be attached to the flange of one of the first and second cable spools. The first arm may be made from a semi-rigid material such that the first arm is configured to curve around the cable spool when it rotated in a clockwise direction. The first arm may be made from a metallic material. The first arm may be flexible partly due to the dimensions of the first arm.

In accordance with yet another aspect, the present disclosure relates to a panel including a slack storage component, a chassis, and a drawer having a height dimension, a width dimension, and a length dimension. The drawer may have a front portion and a base portion. The slack storage component may include an elongated post extending from a circular flange. The circular flange may have a curved sidewall disposed along a peripheral edge of the circular flange. The slack storage component may be rotatably connected to the base portion of the drawer and configured to accommodate a plurality of slack cable lines. The chassis may define an opening that is configured to receive the drawer and two or more cable guides disposed on opposite sides of the opening. The cable guides may be configured bundle together the plurality of slack cable lines.

In some instances, the slack storage component may further include brackets extending from the circular flange. The brackets may be located along the peripheral edge of the circular edge and configured to prevent the slack of the plurality of cable lines from extending past the peripheral edge of the circular flange. The slack storage component may further include a cable clamp. In other instances, the panel may further comprise a cable stop extending from the base portion adjacent to the slack storage component. In other instances, the panel may further comprise a back portion extending from the base portion opposite of the front portion. The cable stop may be located closer to the back portion than the front portion.

In another aspect, the present disclosure relates to a cable storage panel that may comprising a drawer and a chassis. The drawer may have a front portion and a base portion. The base portion may have a first row of posts, a second row of posts, and a third row of posts and separator walls. The first, second, and third rows of posts and/or the separator walls may define cable channels configured to accommodate a plurality of slack cable lines. The chassis may define an opening that is configured to receive the drawer and two or more cable guides disposed on opposite sides of the opening. The cable guides may be configured to bundle together the plurality of slack cable lines. The first and second rows of posts may extend along a first axis and a second axis, respectively, and the first and second axes may be substantially parallel to each other. The third row of posts may extend along a third axis, and the third axis may traverse the first and second axes. The panel may further comprise a first side post and a second side post positioned proximate a first side of the base portion and a second side of the base portion, respectively. The separator walls may be positioned between the first and second rows of posts. One or more posts of the first, second, and third rows of posts may have fins extending therefrom. The third row of posts may comprise a first non-central post, a central post, and a second non-central post, and the central post may be disposed between the first and second non-central posts and proximate to a back portion of the drawer. The back portion being opposite of the front portion. One or more walls of the separator walls may extend from at least one of the first non-central post, central post, and/or second non-central post of the third row of posts. Posts of the first, second, and third rows of posts may be equally spaced apart. The panel may further comprise a first side wall and a second side wall. The first and second side walls may extend from the first and second side posts, respectively. One or more of the separator walls and/or the first and second side walls may define a curved shape. One or more of the separator walls may define a first radius of curvature and a second radius of curvature. The first radius of curvature and the second radius of curvature may be combined to form an S-shaped curve. The cable channels may be configured to prevent cable lines from crossing over other cable lines within the panel.

### BRIEF DESCRIPTION OF THE DRAWINGS

The accompanying drawings are not intended to be drawn to scale. Like reference numbers and designations in the various drawings indicate like elements Also, for purposes of clarity not every component may be labeled in every drawing.

FIG. 1 is a top view of a panel in one configuration in accordance with an aspect of the present disclosure.

FIG. 2 is a top view of the panel of FIG. 1 in another configuration.

FIG. 3 is a top view of the panel of FIG. 1 in yet another configuration.

FIG. 4 is a top view of a panel in accordance with an aspect of the present disclosure.

FIG. 5 is a top view of a panel in one configuration in accordance with an aspect of the present disclosure.

FIG. 6 is a top view of the panel of FIG. 5 in another configuration.

FIG. 7 is a top view of the panel of FIG. 5 in yet another configuration.

FIG. 8 is a top view of a panel in one configuration in accordance with an aspect of the present disclosure.

FIG. 9 is a top view of the panel of FIG. 8 in another configuration.

FIG. 10 is a top view of the panel of FIG. 8 in yet another configuration.

FIG. 11 is a top view of a panel in accordance with an aspect of the present disclosure;

FIG. 12 is a top view of a panel in accordance with another aspect of the present invention;

FIG. 13 is a top view of the panel of FIG. 12 in another configuration;

FIG. 14 is a perspective view of a component of a panel in accordance with an aspect of the present disclosure;

FIG. 15 is a perspective view of a component of a panel in accordance with an aspect of the present disclosure;

FIG. 16 is a top view of a panel in accordance with an aspect of the present disclosure;

FIG. 17 is a top view of the panel of FIG. 16;

FIG. 18 is a top view of the panel of FIG. 16 with cable in one configuration;

FIG. 19 is a top view of the panel of FIG. 16 with cable in another configuration;

FIG. 20 is a top view of a panel in accordance with an aspect of the present disclosure;

FIG. 21A is a top perspective view of a panel and a panel lid in one configuration in accordance with an aspect of the present disclosure;

FIG. 21B is a close-up view a portion of the panel of FIG. 21A;

FIG. 22A is a top perspective view of a drawer extending from the panel of FIG. 21;

FIG. 22B is a close-up view of the drawer of FIG. 22A;

FIG. 22C is a close-up view of a portion of the drawer of FIG. 22B;

FIG. 22D is a close-up view of a portion of the drawer of FIG. 22B;

FIG. 23 is a top view of the drawer of FIG. 22A;

FIG. 24 is a top view of the drawer of FIG. 23 with cable in a configuration for a given cable length;

FIG. 25 is a top view of the drawer of FIG. 23 with cable in a configuration for a given cable length;

FIG. 26 is a top view of the drawer of FIG. 23 with cable in a configuration for a given cable length;

FIG. 27 is a top view of the drawer of FIG. 23 with cable in a configuration for a given cable length;

FIG. 28 is a top view of the drawer of FIG. 23 with cable in a configuration for a given cable length;

FIG. 29 is a top view of the drawer of FIG. 23 with cable in a configuration for a given cable length;

FIG. 30 is a top view of the drawer of FIG. 23 with cable in a configuration for a given cable length;

FIG. 31 is a top view of the drawer of FIG. 23 with cable in a configuration for a given cable length

FIG. 32A is a cross-sectional view of a panel in accordance with an aspect of the present disclosure; and

FIG. 32B is a close-up view of the panel of FIG. 32A.

### DETAILED DESCRIPTION

Examples of systems and methods are described herein. It should be understood that the words “example” and “exemplary” are used herein to mean “serving as an example, instance, or illustration.” Any embodiment or feature described herein as being an “example” or “exemplary” is not necessarily to be construed as preferred or advantageous over other embodiments or features. In the following description, reference is made to the accompanying figures, which form a part thereof. In the figures, similar symbols typically identify similar components, unless context dictates otherwise. Other embodiments may be utilized, and other changes may be made, without departing from the spirit or scope of the subject matter presented herein.

The example embodiments described herein are not meant to be limiting. It will be readily understood that the aspects of the present disclosure, as generally described herein, and illustrated in the figures, can be arranged, substituted, combined, separated, and designed in a wide variety of different configurations, all of which are explicitly contemplated herein.

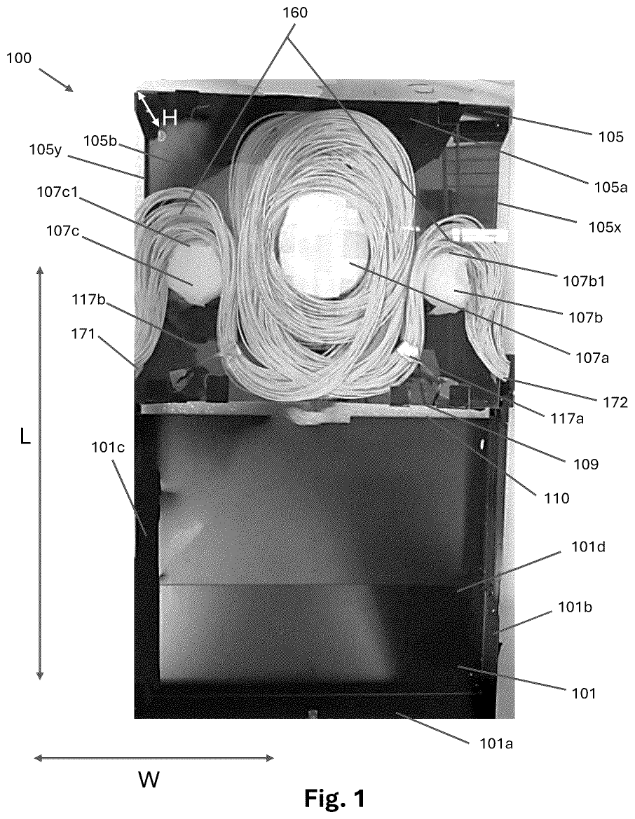

FIGS. 1-3 show a panel 100 of an embodiment that includes a frame or chassis 101, a chassis lid (not shown) that covers the chassis 101, and a drawer 105 insertable into the chassis 101. The chassis 101 and drawer 105 both extend in a length dimension (indicated by L in the depicted reference frame), a width dimension (indicated by W in the depicted reference frame), and a height dimension (indicated by H in the depicted reference frame). More specifically, the chassis 101 includes a first outer wall 101a, a second outer wall 101b, a third outer wall 101c, and a bottom wall 101d. The bottom wall 101d may be generally planar and extends in the W dimension from the second outer wall 101b of the chassis 101 to the third outer wall 101c of the chassis 101. The first outer wall 101a extends in the W dimension from the second outer wall 101b to the third outer wall 101c of the chassis 101. The second and third outer walls 101b/c extend in the L dimension from the first wall 101a to an open side 110 of the chassis 101 and include a cable inlet 171 and a cable outlet 172 proximal to the open side 110. Generally, the first, second, third outer walls 101a/b/c are perpendicular to the bottom wall 101d. The open side 110 of the chassis 101 defines an opening sized and shaped to receive the drawer 105 such that the drawer 105 can slide or pivot in and out of the chassis 101.

Regarding the chassis 101, it is contemplated that the chassis 101 may be configured to fit within a rack or frame of various network systems. While not shown, the chassis may include external brackets and connecting components along with bolt holes required to be properly secured into a rack frame or various other frames. The chassis 101 may be modular in that it is adapted to fit within a large variety of frames with little to no modification to the chassis. Additionally, overall size and shape of panel 100 may be arranged such that it can be accommodated within a panel slot of a rack frame. In this manner, the chassis embodiments described herein may be received by and secured to rack frames used in networking systems using patch panels and the like.

The drawer 105 includes a front wall 105a and a base 105b. The base 105b having a first lateral side 105x and a second lateral side 105y. The first, second, third outer walls 101a/b/c of the chassis 101 and the front wall 105a of the drawer 105 define outer boundaries of the panel 100. The base 105b of the drawer 105 includes a central post 107a, a first side post 107b, and a second side post 107c. Generally, the central post 107a and the first and second side posts 107b/c are elongated cylinders extending in the H dimension from the base 105b. The central post 107a may have a larger diameter or width than the first and second side posts 107b/c, as shown in FIGS. 1-3. However, in other instances, the central post 107a may have the same or similar diameter or width as that of the first and second side posts 107b/c. It is contemplated that the central post 107a may have different shapes and sizes than what is depicted in the above-cited figures. For example, the central post 107a may be structured with several vertical walls or as a cylinder for lines of cable to wrap around to organize such cable within the drawer 105.

The first and second posts 107b/c are positioned on opposite sides of the central post 107a and spaced apart from the central post 107a to allow slack cable or a bundle slack cable to be wrapped around the central post 107a. Side posts 107b/c may be spaced away from the lateral sides 105x/y of the drawer 105 by a distance that at least allows for a designed maximum cable volume to pass therebetween. The side posts 107b/c are positioned on the base 105b such that front facing portions 107b1/c1 of the side posts 107b/c are substantially centered between the front wall 105a and back end 109 of the drawer 105. In other words, when the drawer is in a fully opened position, as shown in FIG. 1, front facing portions 107b1/c1 of the side posts 107b/c are substantially centered between the front wall 105a of the drawer 105 and the cable in/outlet 171,172 of the chassis 101. In this manner, the positioning of the side posts provide just enough space for the drawer to accommodate the cable when the drawer is pushed into the chassis, while allowing the front facing portions 107b1/c1 to act as cable guides when the draw is in the fully opened position.

The base 105b also includes a first arm 117a and a second arm 117b positioned proximate a back end 109 of the base 105b of the drawer 105. The first and the second arms 117a/b both have an opening adapted receive cable or a bundle of cables at one end, which may include a clamp or clamping component to hold the bundle together, and attached to the base 105b at the other end.

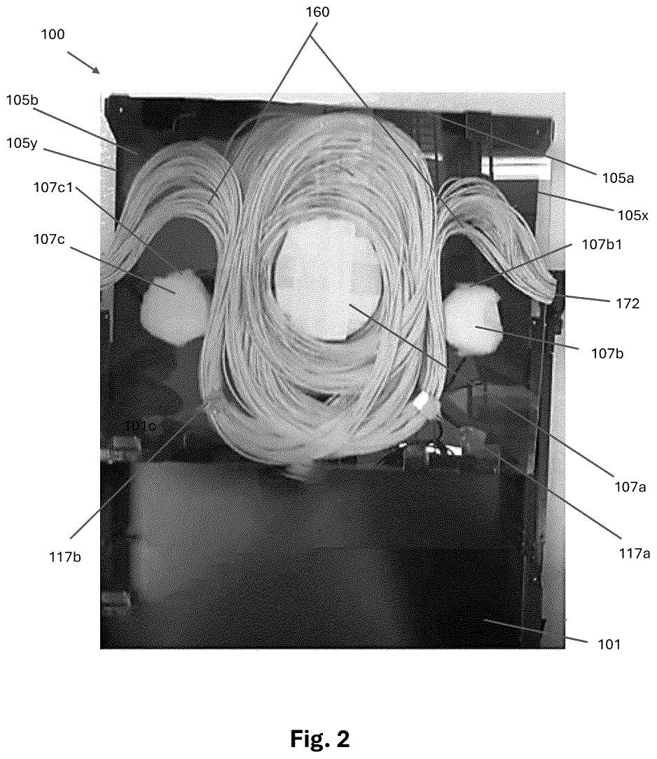

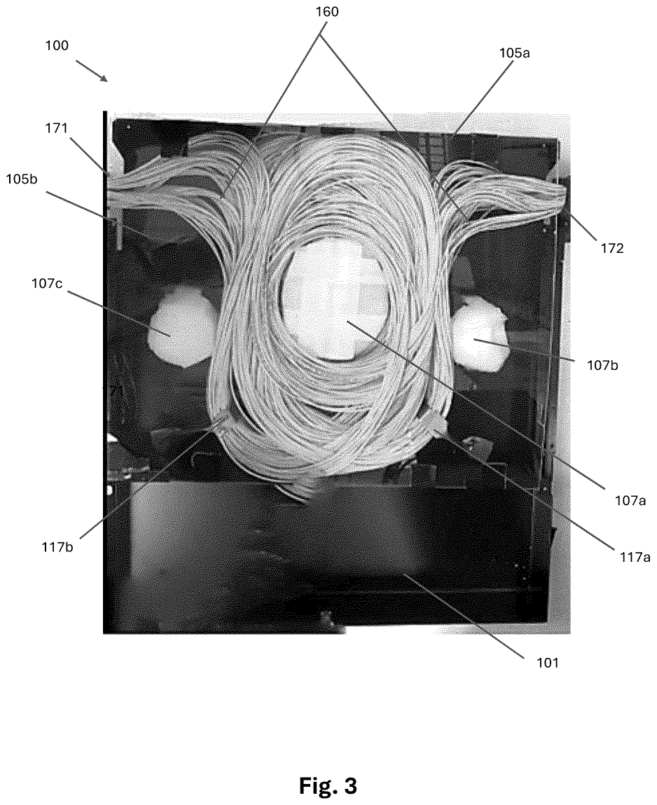

The drawer 105 is configured to move in and out of the chassis 101. FIGS. 1-3 show drawer 105 moving from a closed or near-closed position (FIG. 3) to an intermediate or half-open position (FIG. 2) and then to an open position (FIG. 1). When in the open position, the slack cable 160 may engage and partially wrapped around the first and second side posts 107b/c as the side posts move past a cable inlet 171 and a cable outlet 172 of the panel 100, as shown in FIG. 1. As the drawer 105 moves into the chassis 101 toward the closed position, the slack cable 160 moves away from the first and second side posts 107b/c as the side post move into the chassis 101 and past the cable inlet 171 and the cable outlet 172, as shown in FIGS. 2 and 3. Moving the drawer 105 from the closed position to the open position also moves the first and second side posts 107b/c into a position where they are partially wrapped with the slack cable 160. Generally, when the drawer 105 is moved between the open and closed positions, cable located between the side posts 107b/c does not move. The cable inlet 171 and the cable outlet 172 are adapted to allow the slack cable 160 to pivot therein as the drawer 105 moves between various positions while still maintaining a firm hold on the slack cable 160. Additionally, the first and the second arms 117a/b hold a portion of the slack cable 160 near back end 109 to maintain placement of the cable within the center of the drawer 105. For example, the 117a/b help to ensure any of the cable movement on the sides of the drawer 105 does not impact the placement of the cable located in the center of the drawer 105. In this manner, the panel is adapted to allow the slack cable to bend and move within the drawer as it opens and closes without entangling or damaging the cable.

The drawer 105 further includes rails (not shown) extending from the front wall 105a toward the back end 109 of the chassis 110 in the L dimension. In some embodiments, the rails are configured to engage and slide along tracks respectively disposed on the second and third outer walls 101b/c of the chassis 101 to guide the drawer in and out of the chassis 101. In other embodiments, the drawer 105 may include rails disposed on the exterior surface (not show) of base 105b that are arranged to engage tracks disposed on the bottom wall 101d on the interior of the chassis 101. In either case, the rail and track systems may include ball bearings or rollers or wheels that the tracks to roll or slide within and along a respective track attached to the chassis 101. In some instances, the drawer 105 may be connected to a telescopic guide rail with parts attached on both the drawer 105 and the chassis 101 to allow them to slide with respect to each other. In other instances, the chassis 101 may have a channel or channels that extend(s) along a bottom region of the second and/or third outer walls 101b/c (i.e., side walls) of the chassis 101 and end just before the open side 110 of the chassis 101 such that channel or channel extend along the majority or entirety of the length of the second and third outer walls 101b/c. In such instances, the drawer 105 may include an extended floor portion or portions adapted to slidably connect to and slide within the inside of the channel or channels on both sides thereof. In this manner, the drawer is stabilized horizontally as it is pulled in and out of the chassis. In some cases, an end of the channel located adjacent to the open side 110 of the chassis 101 may be configured to work as stopper to prevent the drawer from coming out of the chassis when pulled to an opened position.

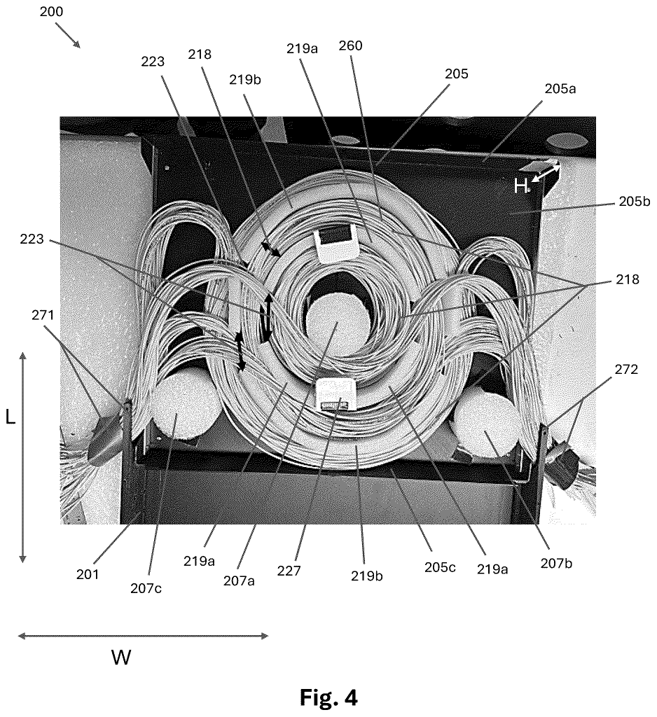

FIG. 4 shows a panel 200 of an embodiment that includes a chassis 201 and a drawer 205 that have the same or similar features as that of panel 100 described above, including a front wall 205a and a base 205b having a central post 207a, first side post 207b and a second side post 207c. The chassis 201 having a cable inlet 271 and a cable outlet 272 that are configured to hold the lines of cable entering and exiting the panel 200. The drawer 205 of further comprising a back wall 205c disposed on an opposite end of the based 205b than the front wall 205a and cable channels 218 defined by first separator walls 219a and second separator walls 219b. The cable channels 218 also extend between the posts (e.g., central, first side and second side posts 207a/b/c) extending from base 205. The first and second separator walls 219a/b concentrically curve around a central post 207a and have side slots 223 to allow side access to the cable channels 218 between the first and second separator walls 219a/b. The cable channels 218 may have widths ranging between 0.25 and 3 inches, more preferably between 0.5 and 2 inches, and side slots may have widths ranging between 0.5 and 4 inches, more preferably between 1 and 3 inches. In this manner, the dimensions and arrangements of the cable channels 218 and side slots 223 may be designed to facilitate easier cable removal from the panel.

The first and second separators wall 219a/b are both arranged in ring-like formations such that the first separate wall 219a outlines an inner ring located within an outer ring defined by the second separator wall 219b. The first and/or second separator walls 219a/b may include horizontal flanges 227 extending partially over one of the cable channels 218 toward central post 207a. The horizontal flanges 227 help contain the cables between the first and second separator walls 219a/b and thus maintain the organization thereof.

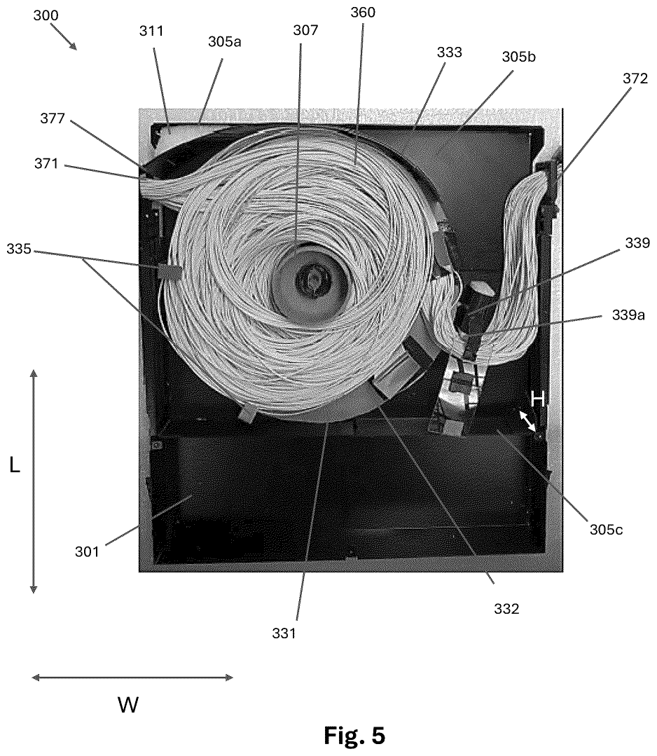

FIGS. 5-7 show a panel 300 of an embodiment that includes a chassis 301 and a drawer 305. The chassis 301 has the same or similar features as the chassis 101 and chassis 201 described above. The drawer 305 has the same walls as the drawer 105 and 205, such as a front wall 305a, a base 305b, and a back wall 305c. The base 305b includes, however, a spool 331 having a central post 307, a flange 332, a curved wall 333, side brackets 335 and a cable clamp or holder 337. The central post 307 is designed for slack cable 360 to be wrapped or coiled around it. The cable holder 337 is disposed on a bottom flange 332 of the spool 331 and is configured to grip or be tightened around a bundle of cables wrapped around the spool. The front wall 305a includes a back wedge 311 to provide support for curved wall 333. The curved wall 333 and side brackets 335 are connected to an outer edge or perimeter of the flange 332 of the spool 331 to prevent cable wrapped or coiled around the spool 331 from extending or expanding beyond the perimeter of the flange 332. In some instances, the curved wall 333 may be configured to create forced rotation of the spool 331 to prevent the cable from harmful tension when the drawer 305 is moved in and out of the chassis 301. For example, the curved wall 333 may be connected to the chassis 301 adjacent to cable inlet 371 at connection point 377, as shown in FIG. 5, such that the curved wall 333 automatically pushes and pulls the spool 331 in clockwise and counter clockwise rotation, respectively, as the drawer 305 moves in and out of the chassis 301. In other instances, when the cable stop 339 is configured to pull the cable as the drawer 305 moves in and out of the chassis 301 and thereby is designed rotate the spool 331, the curved wall 333 may be a fixed wall extending from the base 305b.

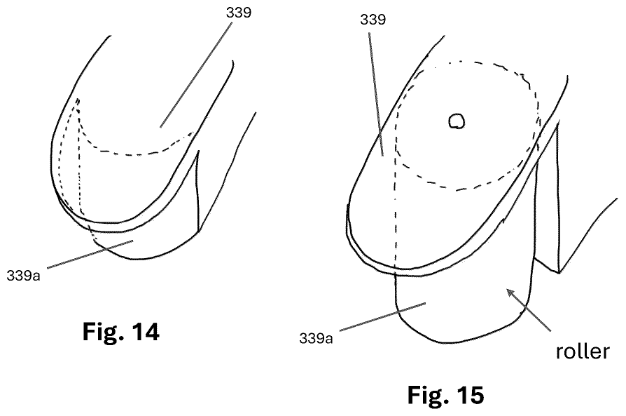

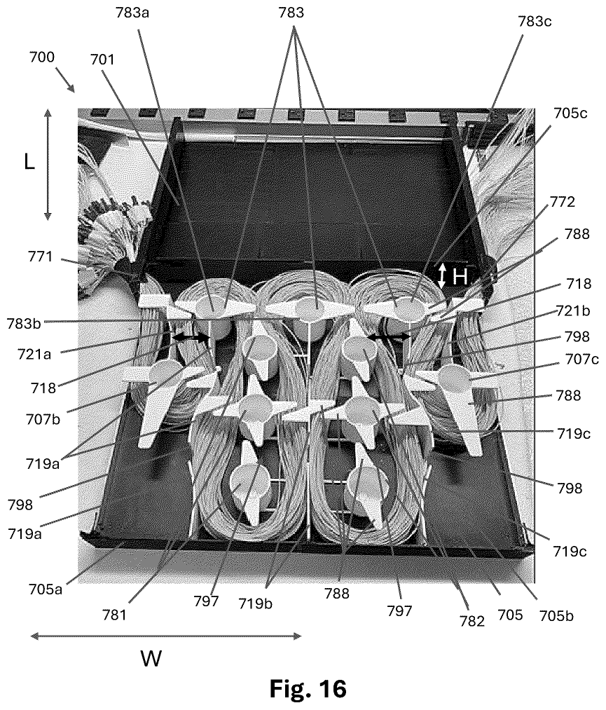

The base 305b further includes a cable stop 339 disposed closer toward the back wall 305c than the front wall 305a. The cable stop 339 has a rear facing portion 339a that is configured to allow cable to easily slide against or past it. For example, the rear facing portion 339a may have a slippery surface or include a small rotatable element (e.g., a small cylindrical roller) to facilitate such movement of the cable, as shown in FIGS. 14 and 15. The cable stop 339 may be immovably fixedly to base 305b, and the spool 331 may be rotatably attached to the base 305b.

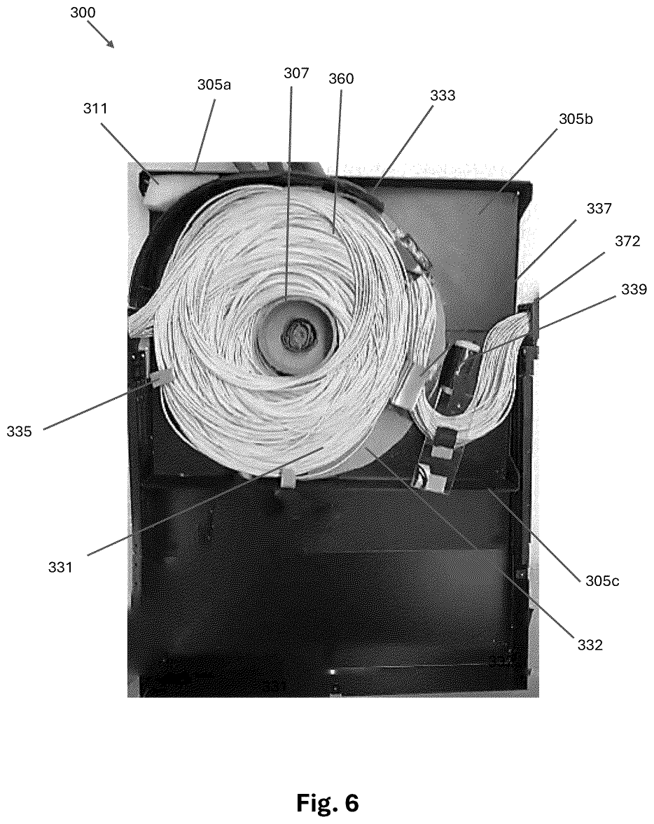

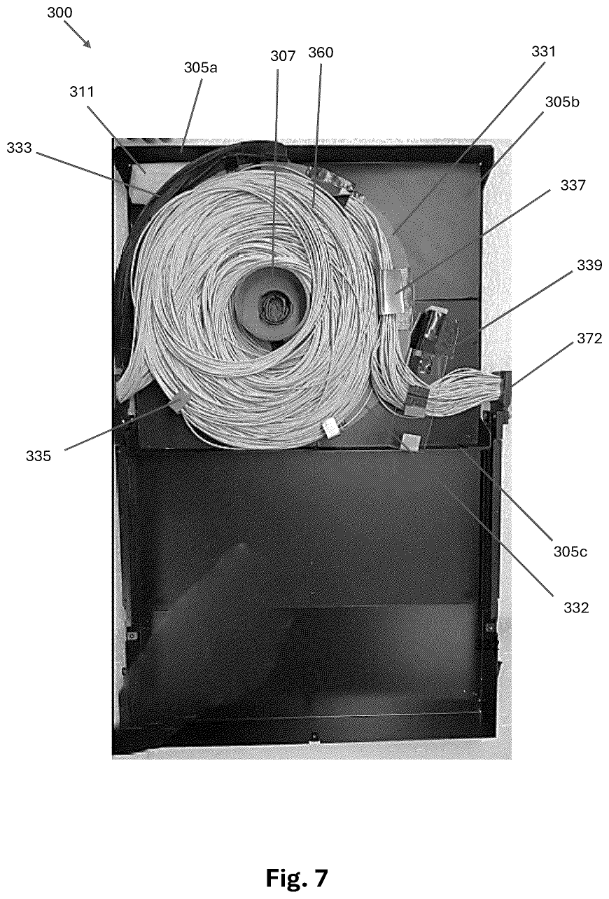

In some instances, the cable in panel 300 may be organized in the following arrangement. Slack cable 360 may be routed through cable inlet 371 and wrapped or coiled around spool 331. Slack cable 360 may then extend from the spool 331 and routed around or through the cable stop 339 such that the cable is pulled toward the third wall 301c of the chassis 301 when the drawer 305 is pushed or moved therein. As the drawer 305 moves in and out of the chassis 301, the slack cable 360 is allowed to move based on the rotatability of the spool 331. For example, the spool 331 is adapted to rotate counter clockwise as the drawer 305 is removed from the chassis 301 and clockwise as the drawer 305 is moved into the chassis 301. In this manner, the spool 331 is configured to rotate as the drawer 305 is moved in and out of the chassis 301, as illustrated in FIGS. 5-7 depicting the drawer 305 moving from a closed or near-closed position (FIG. 5) to an intermediate or half-open position (FIG. 6) and then to an open position (FIG. 7). As noted above, rotation of the spool 331 prevents the cable from experiencing harmful tension when the drawer 305 is moved in and out of the chassis 301.

Regarding the cable spool 331, flange 332 may a circular flange and/or may include circular flanges concentric with a circular drum such that the circular flange lie in, or parallel to, the W-H plane, and is accommodated in the drawer 301 such that the flanges and drum rotate about an axis running through the center of the flanges and drum. The cable spool 331 may have slack cable wound about the drum and extending to and from the drum from opposite sides of the drawer 305 from a cable inlet and a cable outlet.

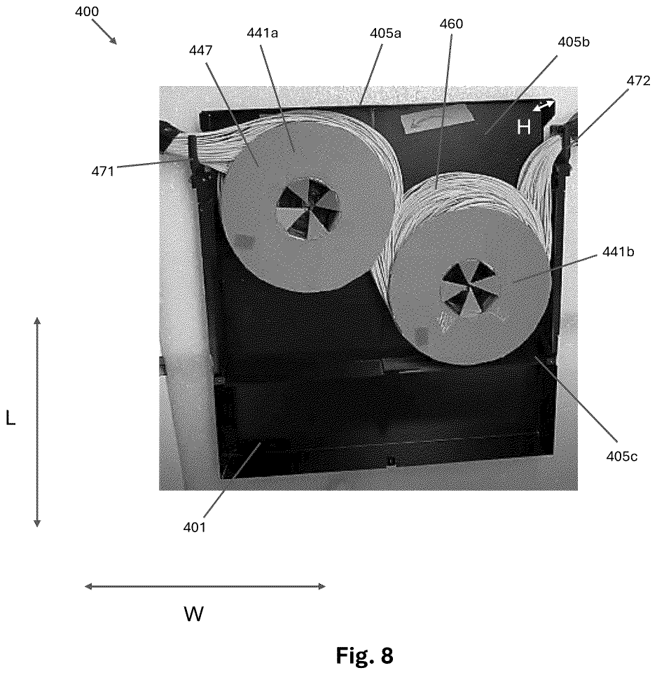

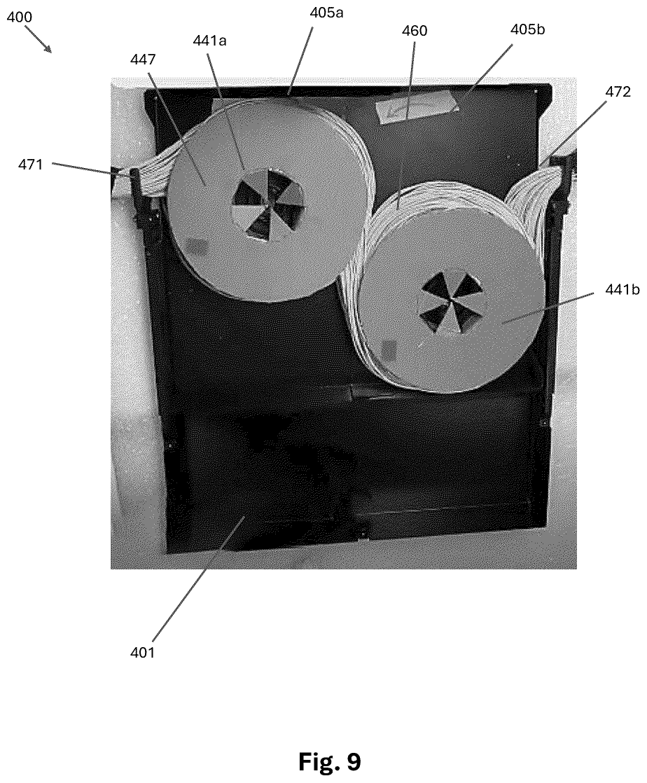

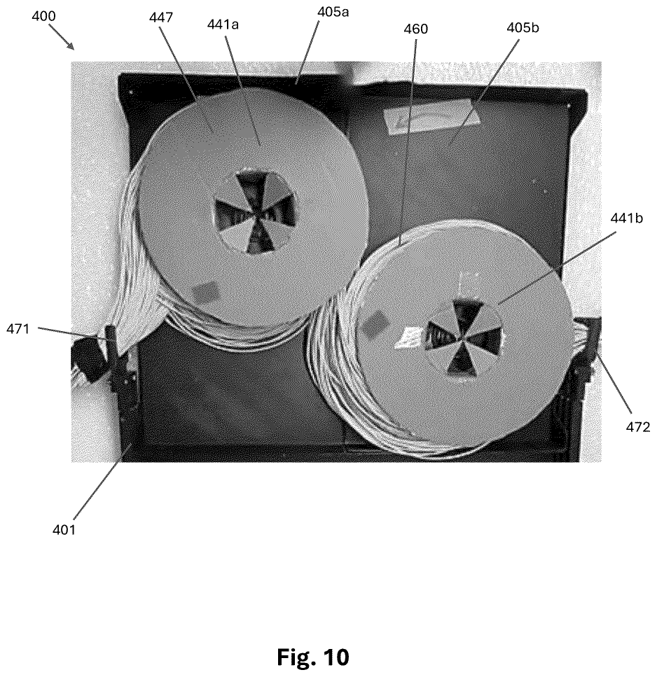

FIGS. 8-10 show a panel 400 of an embodiment that includes a chassis 401 and a drawer 405. The chassis 401 has the same or similar features as the chassis 201 and chassis 301 described above. The drawer 405 has the same walls as the drawer 205 and 305, such as a front wall 405a, a base 405b, and a back wall 405c. The base 405b includes, however, a first spool 441a and a second spool 441b that each have having a top flange 447 and a bottom flange (not shown). The top and bottom flanges may be circular and concentric with each other. The first and second spools 441a/b are generally smaller than the spool 331 such that both spools can be positioned adjacent to each other within drawer 405. In this arrangement, slack cable 460 may be wrapped and stored around both the first and second spools 441a/b before exiting the panel 400, as shown in FIG. 8. The first and second spools 441a/b are rotatably attached to the base 405b of the drawer 400. In this manner, the first spool 441a and the second spool 441b are configured to rotate counter clockwise and clockwise, respectively, as the drawer 305 is moved out of the chassis 301, as illustrated in FIGS. 8-10 depicting the drawer 405 moving from a closed or near-closed position (FIG. 8) to an intermediate or half-open position (FIG. 9) and then to an open position (FIG. 10); and vice versa when the drawer 405 is moved from the open position to the closed position (i.e., into the chassis).

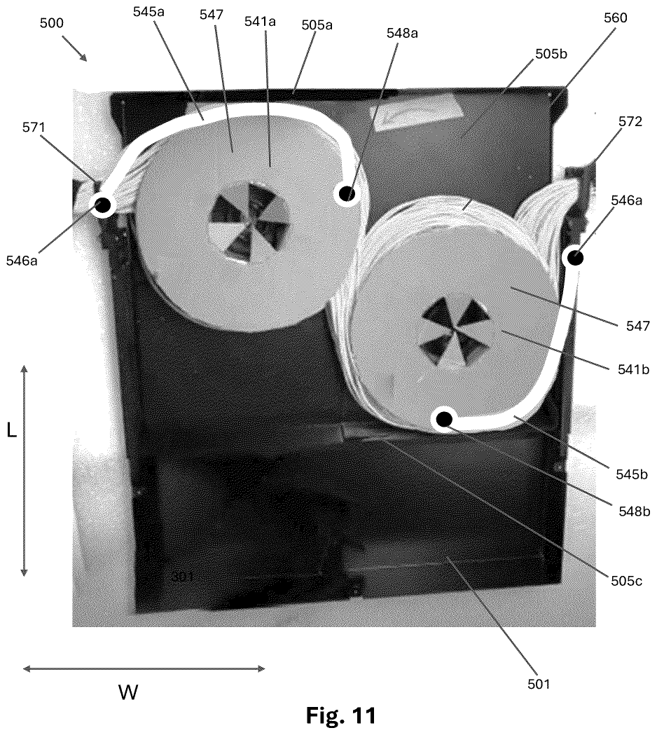

FIG. 11 shows a panel 500 of an embodiment that includes a chassis 501 and a drawer 505 that have the same or similar features as that of the panel 400 described above, including a first spool 541a and a second spool 541b. The drawer 505 further includes a first flexible arm 545a and a second flexible arm 545b that are each connected to the chassis 501 at a first end 546a/b and connected the first and second spools 541a/b, respectively, at a second end 548a/b. For example, the first flexible arm 545a may be attached to a top flange 547a of the first spool 541a and the second flexible arm 545b may be attached to a top flange of 547b of the second spool 541b. The first and second flexible arms 545a/b may be fixedly attached or pivotably attached to the first and second spools 545a/b, respectively. The first and second flexible arms may be made from a semi-rigid material or materials, e.g., elastic plastic like Nylon and/or tempered metal or metal alloy. In some instances, the flexible arms may be flexible due to dimensional features such as thickness. For example, the flexible arms may be made from a thin metal material. In this manner, the first and the second flexible arms are configured to push and pull on the first and second spools to help them rotate as the drawer is opened and closed.

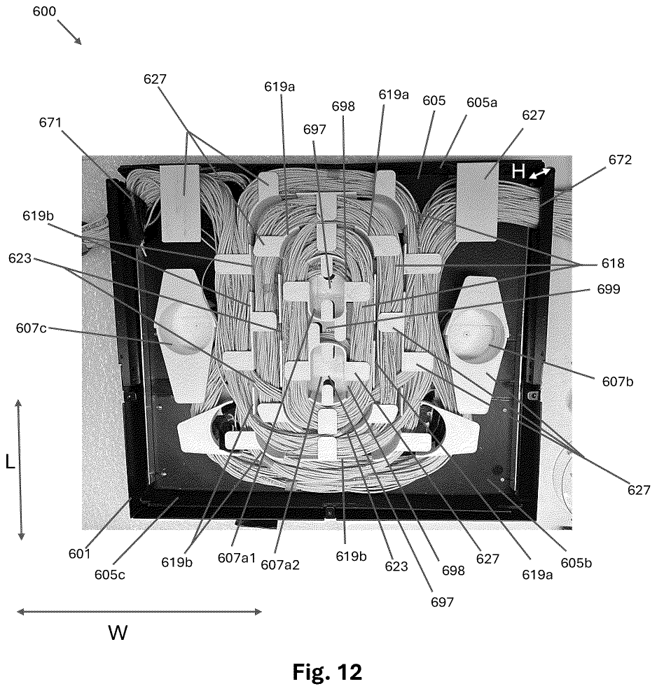

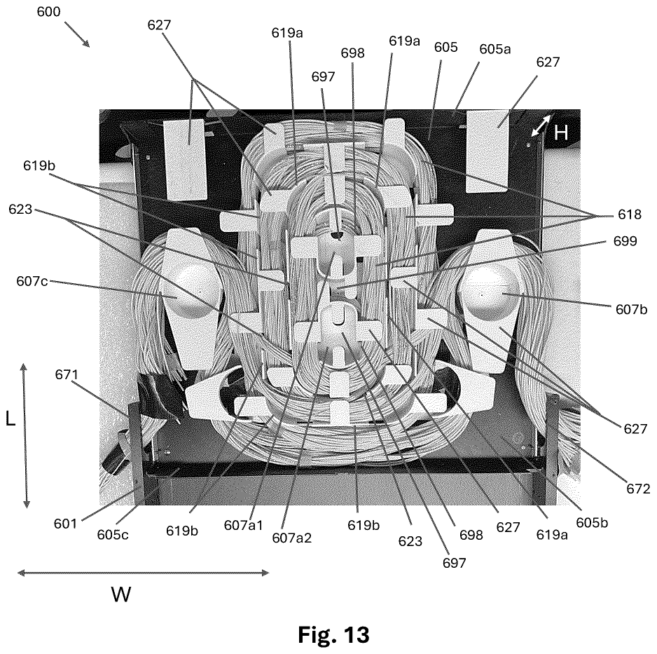

FIGS. 12 and 13 show a panel 600 of an embodiment that includes a chassis 601 and a drawer 605 that have the same or similar features as that of panels 100 and 200 described above, including a front wall 605a and a base 605b having a first side post 607b, a second side post 607c, and a back wall 605c disposed on an opposite end of the based 605b than the front wall 605a. The chassis 601 having a cable inlet 671 and a cable outlet 672 that are configured to hold the lines of cable entering and exiting the panel 600, respectively. The drawer 605 of the panel 600 further comprises a first central post 607a1, a second central post 607a2, and cable channels 618 defined by first separator walls 619a and second separator walls 619b. The cable channels 618 extend between the first side and second side posts 607b/c. The first and second central posts 607a1/a2 are spaced part from each other such that a central channel 699 is located therebetween. The central channel 699 allows cable to be positioned between the central cable posts 607a1/a2. The first and second central posts 607a1/a2 also include side gaps 698 such that cable may extend through an interior region 697 of the central posts 607a1/a2, as shown in FIGS. 12 and 13.

The first and second separator walls 619a/b are positioned around the first and second central posts 607a1/a2 and define paths extending therearound. In some instances, the cable channels may define concentric paths centered around the central posts 607a1/a2. The separator walls 619a/b include wall segments 619c that are spaced apart and aligned with each other to define the separator walls 619a/b such that the first separator wall 619a is disposed around the central posts 607a1/s2 and within the second separator wall 619b. The separator walls 619a/b include side slots 623 between each of the wall segments 619c of the separator walls to allow lateral access to the cable channels 618. In some embodiments, one or more of the wall segments 619c may have a side groove or notch adapted and positioned to receive a line or lines of cable tightly fitted therein. The cable channels 618 may have widths ranging between 0.25 and 3 inches, more preferably between 0.5 and 2 inches, and side slots may have widths ranging between 0.5 and 4 inches, more preferably between 1 and 3 inches. In this manner, the dimensions and arrangements of the cable channels and side slots described herein may be designed to facilitate easier cable storage within and cable removal from the panel. For example, the side slots provide multiple passages for cables to pass from one cable channel to another cable channel, making it easier to fish out one cable line by hand as needed.

The first and second separators wall 619a/b may be arranged in ring-like or track-like formations such that the first separate wall 619a outlines an inner ring located within an outer ring defined by the second separator wall 619b, the inner ring having a smaller diameter or width than that of the outer ring. Generally, the second separator wall 619b tracks the path established by the first separator wall 619a, and vice versa, such that the separator walls are evenly spaced apart from each other. These ring-like formations delimited by the separator walls 619a/b may be circular, oval, rectangular, or other similar patterns. The cable channels 618 may have widths ranging between 0.25 and 3 inches, more preferably between 0.5 and 2 inches. In this manner, the separator walls define organized cable channels used to store cable within the panel.

The first and second central posts 607a1/a2 and some of the wall segments 619c of the first and/or second separator walls 619a/b may include horizontal flanges 627 extending partially over one of the cable channels 618. The front wall 605a and the side posts 607b/c may also include one or more horizontal flanges 627 extending therefrom. The horizontal flanges 627 help contain the cables between and within the cable channels 618. For example, the horizontal flanges 627 on side posts 607b/c may be relatively longer horizontal flanges than the other flanges to prevent the cables from jumping out while the cables on the side of the drawer 605 move against the drawer when sliding the drawer in and out of the chassis 601. In such instances, the longer horizontal flanges may touch or overwrap each other, or even define a removable cover, to prevent the moving cable from jumping out of the drawer.

In some embodiments, the panels 100, 200, 300, 400, 500, 600 and 700 may have a one rack unit size. A rack unit (RU) size is typically defined as 1.75 inches of H dimension space. Moreover, for 19-inch rack frames, a 1 (one) RU patch panel occupies 1.75 inches of H dimension by about 17 inches of W dimension, or when the width of the mounting portions is included, 1.75 inches of H dimension by about 19 inches of W dimension. Nevertheless, a 1 RU patch panel may occupy other dimensions. For example, for 23-inch rack frames, a 1 RU patch panel occupies 1.75 inches of H dimension by about 21 inches of W dimension, or when the width of the mounting portions is included, 1.75 inches of H dimension by about 23 inches of W dimension. The panels 100, 200, 300, 400, 500, 600 and 700 may have a 1 RU size in the H dimension and W dimension. That is, in one embodiment the patch panel may extend 1.75 inches in the H dimension and about 19 inches in the W dimension, when the W extent includes the width of brackets included therewith. In another embodiment, the patch panels 100, 200, 300, 400, 500, 600 and 700 may extend 1.75 inches in the H dimension and about 23 inches in the W dimension, when the W extent includes the width of brackets included therewith.

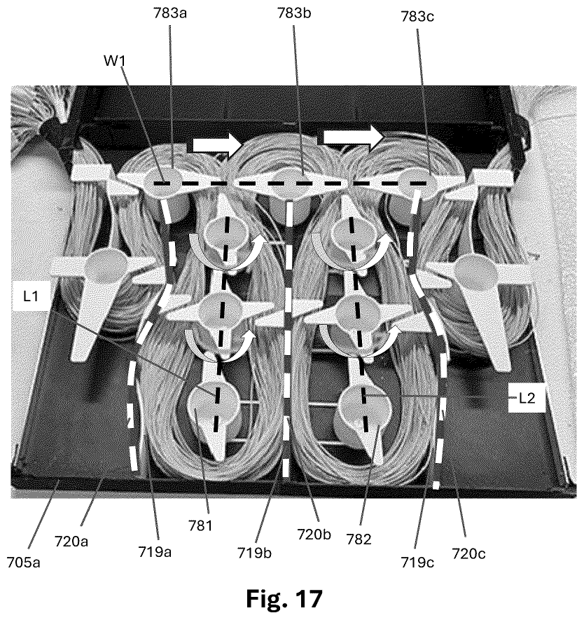

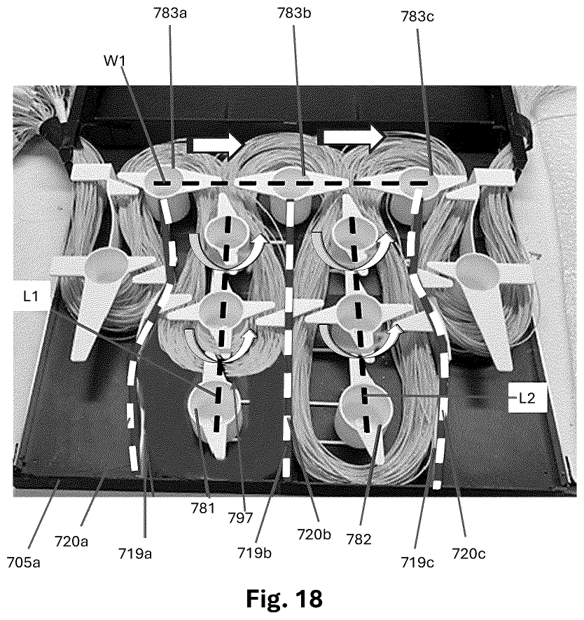

In another aspect, FIGS. 16 and 17 show a panel 700 of an embodiment that includes a chassis 701 and a drawer 705 that have the same or similar features as that of panels 100, 200, 600, etc. described above, including a front wall 705a and a base 705b having a first side post 707b, a second side post 707c, and a back wall 705c disposed on an opposite end of the base 705b than the front wall 705a. The chassis 701 having a cable inlet 771 and a cable outlet 772 that are configured to hold the lines of cable entering and exiting the panel 700, respectively. The drawer 705 of the panel 700 further comprises a first row of posts 781, a second row of posts 782, a third row of posts 783, and cable channels 718 defined by separator walls 719a, 719b, 719c and the first, second, and third row of posts 781, 782, 783. The first and second row of posts 781 and 782 are align along axis L1 and axis L2, respectively, extending along the L dimension, as shown in FIG. 17. The third row of posts 783 are aligned along axis W1 that extends along the W dimension, also shown in FIG. 17. The first side post 707b and the second side post 707c have a first sidewall 721a and a second sidewall 721b, respectively, extending therefrom. The first and second sidewalls 721a, 721b generally do not extend beyond the third row of posts 783 in the L dimension. In some embodiments, however, an end of the first and second sidewalls 721a, 721b may be positioned closer to the back wall 705c of the drawer 705 than the third row of posts 783.

The cable channels 718 also extend around and between the first, second, and third rows of posts 781, 782, 783. In particular, each of the three posts of the third row of posts 783a, 783b, 783c has one of the separator walls 719a, 719b, 719c extending from the respective post to the front wall 705a. Between the separator walls 719a, 719b, 719c, the first and second rows of posts 781 and 782 are positioned to further define the cable channels 718. In this way, the separator walls 719a, 719b, 719c create three barriers 720a, 720b, 720c, as shown in FIG. 17, that separate different sections of the panel 700 to define one or more pathways for cable to be threaded through the panel 700. In this manner, the separation walls prevent cable lines from crossing over other cable lines, which helps to prevent tangling cable lines in the panel and allows for much easier removal of the cable when needed.

Generally, each post of the rows of posts 781, 782, 783 includes fins 788 extending from a top end therefrom to help retain the cable lines within the cable channels 718. Some or all of the posts of the first, second, and/or third rows of posts 781, 782, 783 may be hollow structures to reduce the weight of the drawer 705. The separator walls 719a, 719b, 719c also include fins 788 extending therefrom and over cable channels 718. In various instances, one or more walls of the separator walls 719a, 719b, 719c may define a double curve (i.e., an S-shaped curve) or a single curve (i.e., a C-shaped curved). In other instances, one or more walls of the separator walls 719a, 719b, 719c may be substantially linear.

The separator walls 719a, 719b, 719c also include sidegaps 798 extending therebetween. The sidegaps 798 allow for finger access into the cable channels 718 so that cables may be easily removed or organized. For example, when a cable needs to be removed (or repositioned), a user may insert one or more fingers through one or more sidegaps of the sidegaps 798 to retrieve (or move) the cable that needs to be removed (or repositioned). In this manner, the sidegaps 798 provide users with quick and efficient access to cables within the cable channels 718 and thereby facilitate convenient removal and organization of cable stored within the panel 700.

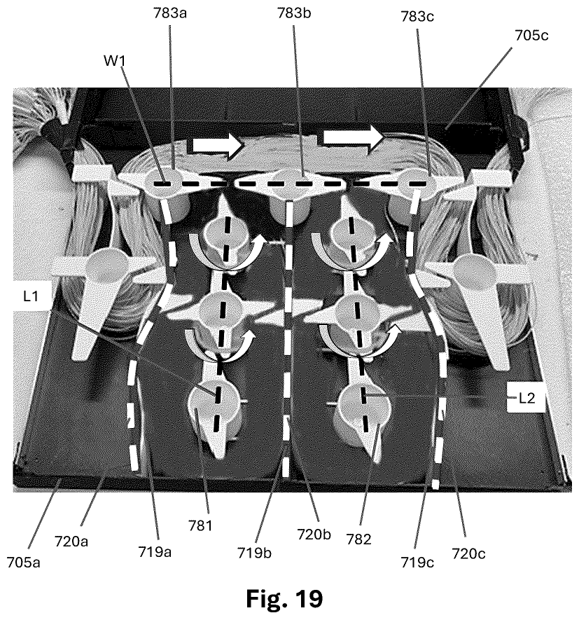

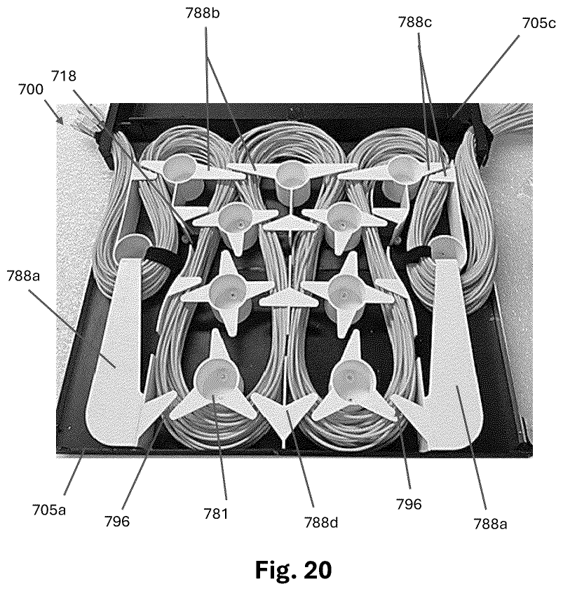

The first, second, and third rows of posts 781, 782, 783 are spaced apart from each other such that gaps 797 are formed therebetween, as shown in FIG. 16. In some instances, the sidegaps 798 align with each other and with the gaps 797 between the first, second, and third rows of posts 781, 782, 783. In the event a cable line (i.e., cable slack) is not long enough to extend through the full length of the cable channels 718, it may be placed in the gaps 797 (i.e., between the individual posts of the first, second, and third rows of posts 781, 782, 783), as shown in FIG. 18 and as indicated by the arced arrows in FIGS. 17-19, to fit a shorter pathway through the panel 700. Alternatively, cable slack may extend along the back wall 705c of the panel 700 for an even shorter path through the panel 700, as shown in FIG. 19. In this manner, the panel 700 is configured to accommodate various lengths of cable slack while still preventing crossover of the cable.

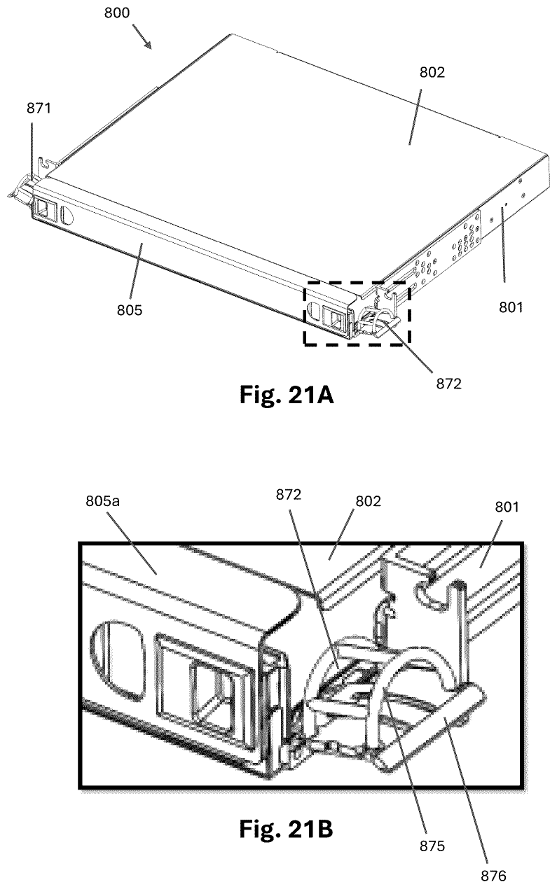

In some other embodiments, the panel 700 may include a variety of top flanges or fins 788 designed to hold cable in an organized arrangement within the cable channels 718 of the panel 700. For example, as shown in FIG. 20, the panel 700 may have large fins 788a, medium size fins 788b, and/or small fins 788c. These fins may define various shapes including, but not limited to, triangular, rectangular, trapezoidal, rhombohedral, etc. Additionally, two fins 788 may be placed next to each other to form a triangular or chevron-like formation 788d. In some instances, the two or more of the fins 788 may extend toward each other from opposite sides of a cable channel. In such instances, the two or more fins 788 may be spaced apart just enough to define a finger slot 796 to allow a user to fit one or more fingers between the two or more fins to access the cable lines thereunder as needed.

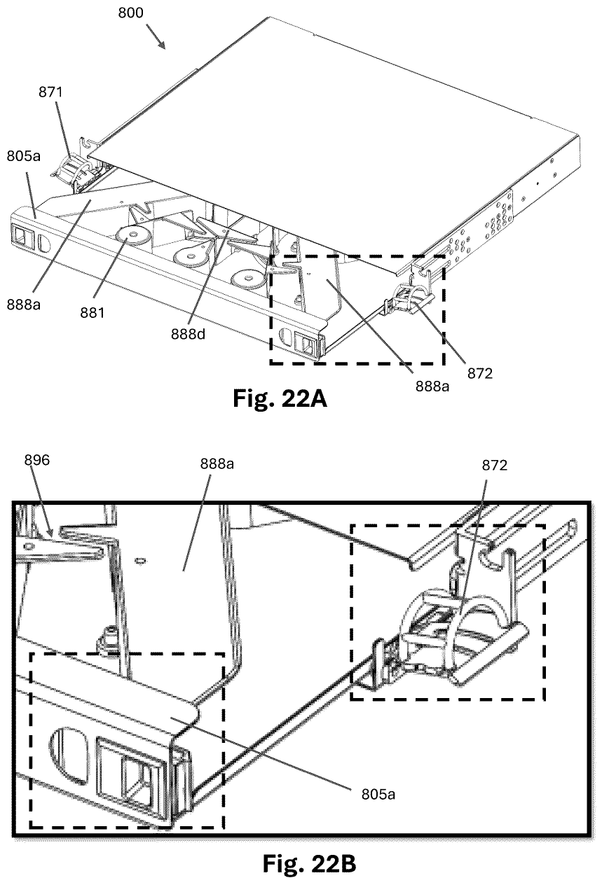

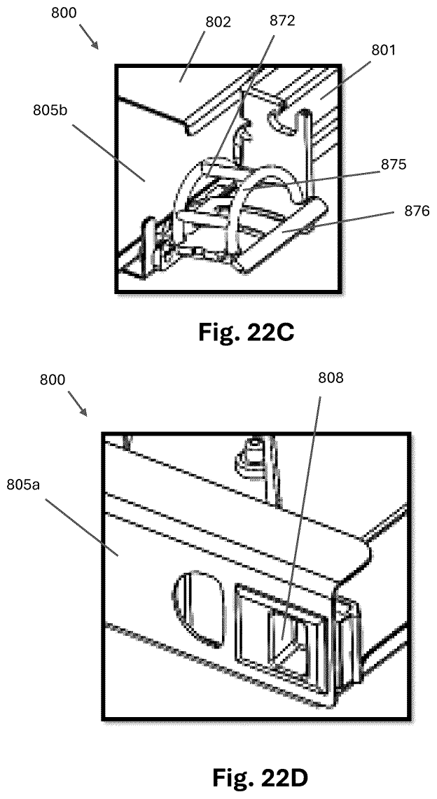

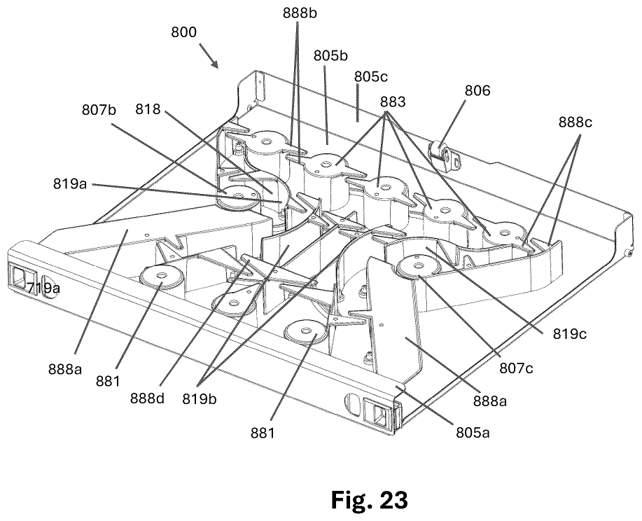

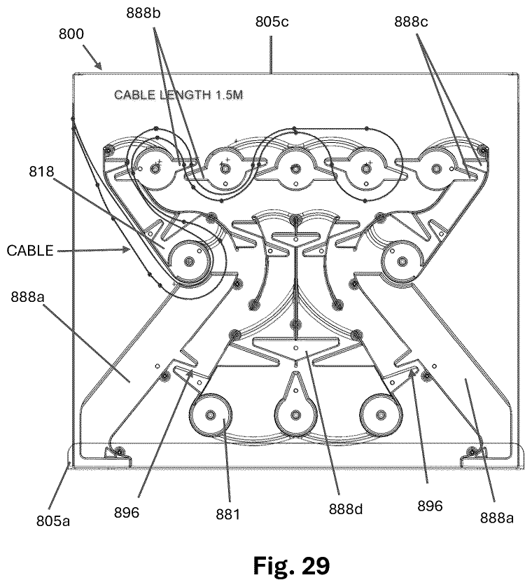

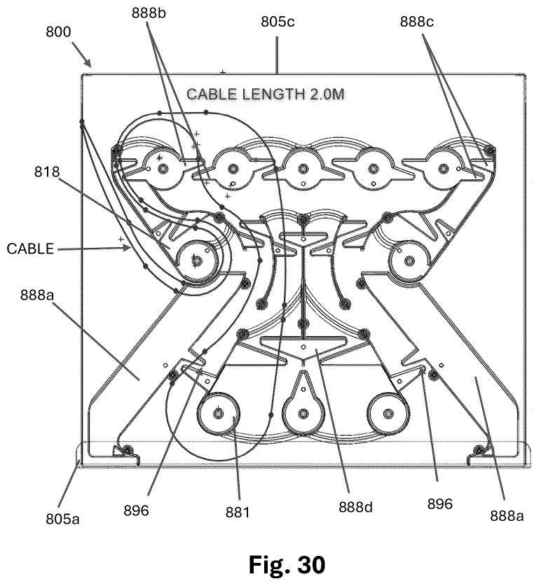

In another aspect, FIGS. 21A-31 show a panel 800 of an embodiment that includes a chassis 801 and a drawer 805 that have the same or similar features as that of panels 100, 200, 600, 700 etc. described above, including a front wall 805a and a base 805b having a first side post 807b, a second side post 807c, and a back wall 805c disposed on an opposite end of the base 805b than the front wall 805a. Back wall 805c includes a roller 806 that may be spring loaded and that extends away from the base 805b of the drawer 805. Edges of the base 805b of drawer 805 are rolled or folded to conceal sharp metal edges and corners that could cut cables as they hang out of the drawer. Drawer 805 also includes holding slot 808, as shown in FIG. 22D, configured to be gripped by a user when the drawer is pulled and pushed in and out of the chassis 801. Drawer 805 includes cable channels 818 that are defined by separator walls 819a, 819b, 819c, individual posts 881, and a row of posts 883. In some instances, multiple rows of posts may be used as described above. Panel 800 may further include flanges or fins 888 such as large fins 888a, medium size fins 888b, and/or small fins 888c, as shown in FIG. 23.

The chassis 801 includes a lid 802, a cable inlet/outlet 871, and another cable inlet/outlet 872. The cable inlet/outlets 871, 872 each include a strap 875 configured to wrap around the lines of cable entering and exiting panel 800 and hold them in place at such entry/exit points of the panel. Strap 875 may be made from flexible polymer material including silicone rubber and the like such that the strap is configured extend around and bound together any number of cable lines (e.g., 1 to 100). Strap 875 may be attached to chassis 801 via an anchor strap 876 that securely attaches strap 875 to the side thereof, as shown in FIG. 21B and FIG. 22C. For example, anchor strap 876 may include a Velcro strap or a similar securement.

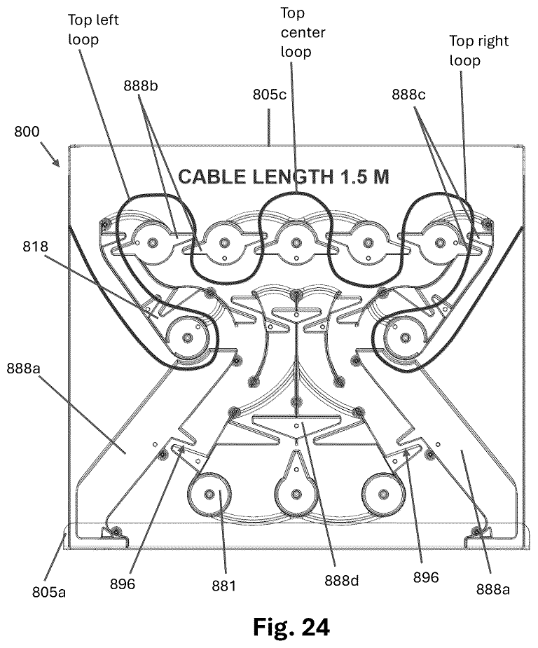

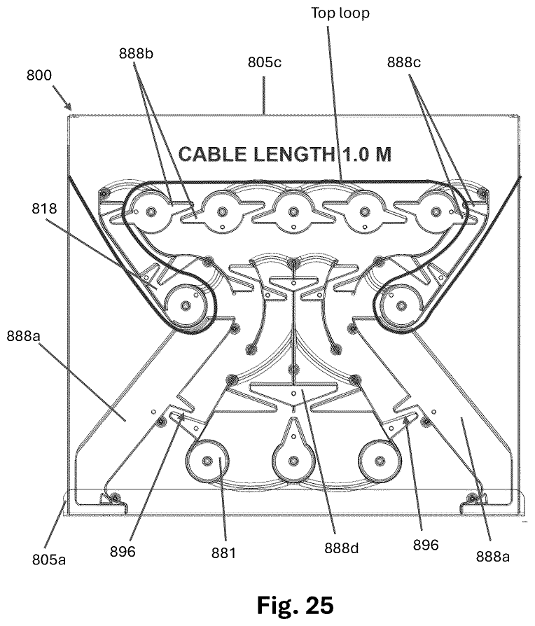

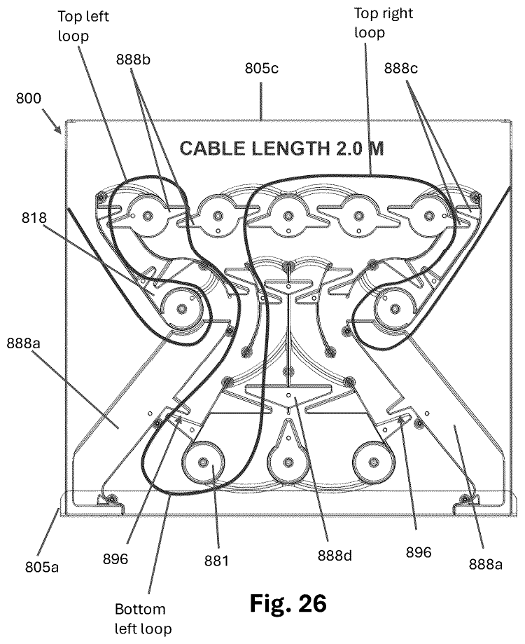

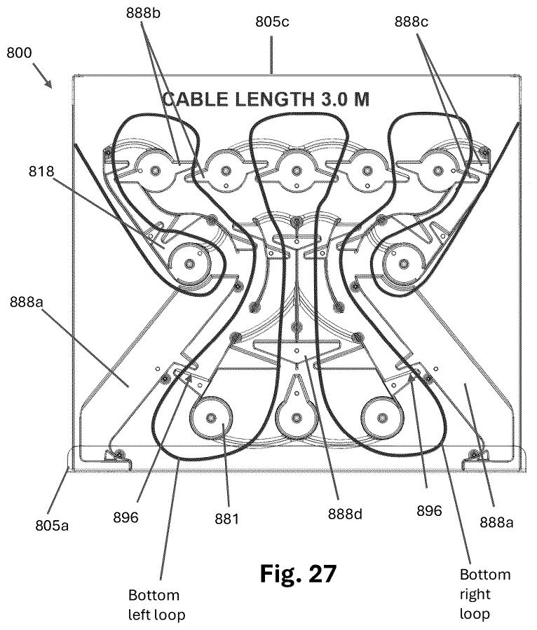

As shown in FIGS. 24-31, cables of various lengths may be placed or threaded through panel 800 at various configurations designed to store excess cable length in an orderly manner. For instance, FIGS. 24-27 show four different cable configurations each designed for different lengths of cable (e.g., 1.0 m, 1.5 m, 2.0 m, and 3.0 m). When a cable line has 3.0 m of slack cable that needs to be stored, it is arranged in the panel as shown in FIG. 27, with the cable extending in one side of the panel (e.g., inlet 871) and out the opposite side (e.g., outlet 872). The cable configuration shown in FIG. 27 is intentionally arranged to facilitate a simple transition to the 2.0 m, 1.5 m, and 1.0 m configurations (shown in FIGS. 26, 25, and 24), and vice versa, without needing to entirely removing the cable from the panel. Instead, a portion of the slack cable is removed from a channel such that the remaining cable extends through the panel in a slightly different configuration. For example, a 3.0 m of slack cable is stored in the configuration show in FIG. 27. Then, when a user needs to remove 1.0 m of the slack cable from the panel, the bottom left loop of the slack cable is removed from cable channels and the remaining cable is rerouted such that the cable extends from the bottom left loop to a top right loop place around one, two or three posts as shown in FIG. 26. If additional 1.0 m of cable is needed, then the user removes the bottom left loop from the cable channels and reroutes the remaining 1.0 m of slack cable to form on top loop as shown in FIG. 25. Alternatively, the cable may be routed between the posts of the channel if less or more cable length needs to be stored or removed, as shown in FIG. 24. In this manner, when a portion of cable needs to be stored or removed from the panel, a user can easily rearrange the slack cable already stored therein to allow for less or more as needed.

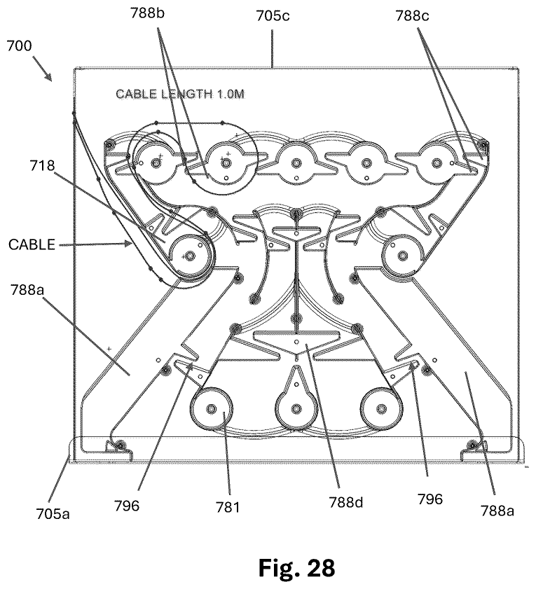

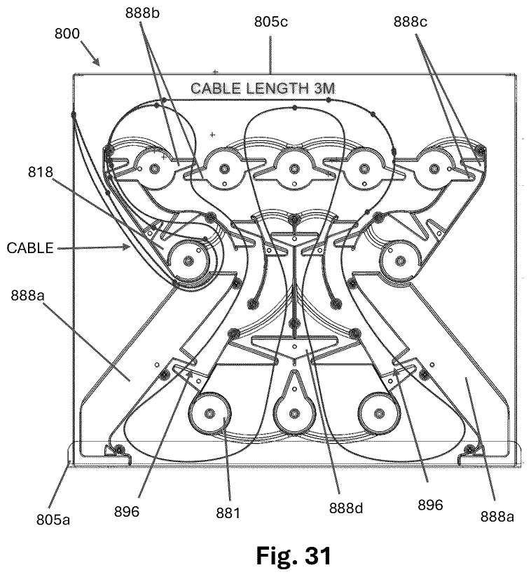

Additionally, slack cable may be stored in a configuration such that it enters and exits the panel at the same point (e.g., inlet/outlet 871 or inlet/outlet 872) as shown in FIGS. 28-31. Such cable configures are designed to easily transition from one configuration to another (e.g., 3.0 m configuration shown in FIG. 31 rerouted 1.0 m configuration shown in FIG. 28) without entirely removing and rethreading the cable through the panel, similar to cable configurations shown in FIGS. 24-27 described above. In this manner, panel 800 is designed to store cable in various configurations that may be employed based on a users' needs.

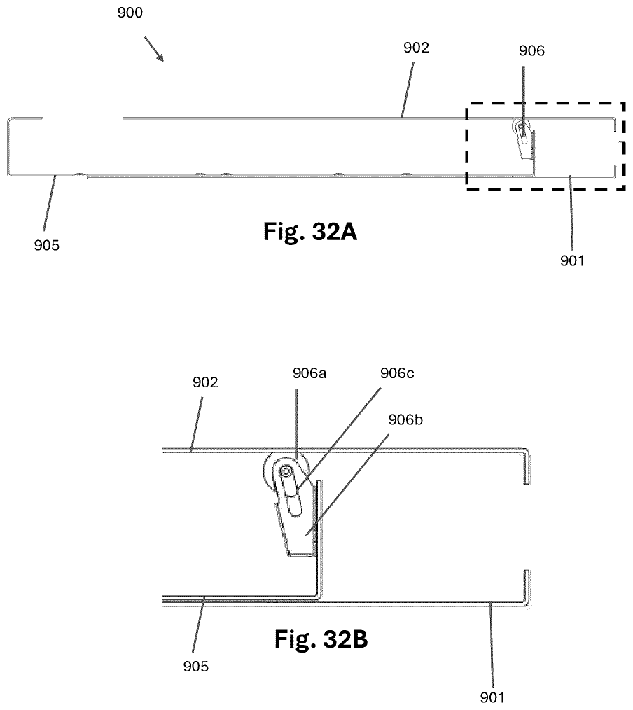

In another aspect, the present disclosure relates to a panel assembly configured to protect stored cable when external force applied to the panel. For example, as shown FIGS. 32A and 32B, a panel 900 of that includes a chassis 901, lid 902, and drawer 905. The drawer includes a roller 906 having as a wheel 906a rotatably attached to the drawer 905 via a bracket 906b. Roller 906 may be fitted into a track extending along the underside or inner side of the lid 902 of the panel 900. Wheel 906a of the roller 906 may be spring loaded such that it may shift toward and away from the drawer 905 while attached to the bracket 906b. For example, an axis of the wheel 906a may be positioned within a slot 906c of the bracket 906b and attached to a spring (not shown) that pushes the wheel up against the lid 902, as shown in FIG. 32B, to support the lid when an external force is applied (e.g., weight of another panel or cable).

Because cable storage panels are typically made of thin Sheetmetal, they are susceptible to deform when external forces are applied. Such deformation can cause the panel's contents that are housed in its drawer and/or the drawers' back wall top scrub or catch against the inner surface of the panel's lid or the lid of the chassis. This creates extra friction that makes it difficult to access the contents of the panel and could potentially damage the contents thereof. In such instances, the roller 906 of panel 900 is designed as an internal mechanism that pushes lid 902 away from drawer 905 to ensure there is proper clearance for the drawer and its contents to be pulled away from the chassis 901. In this manner, panel 900 is designed to ease the removal of the drawer for the chassis and protect the contents stored therein. While only wheel or roller is shown in the figure, additional wheels and roller of similar configuration may be included to further ease movement of drawer 905. Additionally, it is contemplated that the roller 906 of panel 900 could be used in any of the other panels included those set forth above.

The panels 100, 200, 300, 400, 500, 600, and 700 may further include a plurality of slack cable 160. The slack cable 160, 260, 360, 460, 560 may be fiber optic cable and may, for example, couple to connectors external to the panels. The slack cable 160 may be routed from one side of the panels (e.g., first outer wall 101a) to the other (e.g., second outer wall 101b) via cable channels (e.g., cable channels 218) or cable spool or spools (e.g., spool 331 and spools 441a/b). In this manner, these panels are adapted to organize and manage slack cable stored within a cable network system. For example, slack or excess cable is stored in one of the panels by feeding the cable through a cable inlet (e.g., cable inlet 271) disposed on a side of the panel. Then, the cable is wrapped around the cable storage component(s) or system in the drawer of the panel, e.g., but not limited to, central post 107a and 207a, cable channels 218, spool 331, dual spools 441a/b, etc., to organize the excess cable in an orderly fashion. The cable storage component or systems are located within a drawer to allow for easy accessibility to the excess cable. After cable has been wrapped around the storage system, then the cable exits the panel via a cable outlet (e.g., cable outlet 272). In some instances, the cable is routed around cable stops or holder (e.g., cable stop 339) to control the lines of cable extending from the cable storage component or system. Panels may be located with a rack frame near connection ports housed in other panels where the ends of the cables are connected. In this manner, the slack cable storage panels disclosed herein provide an organized apparatus to manage excess cable while also making it readily accessible.

Embodiments of the present technology include, but are not restricted to, a panel including a chassis and a drawer disposed within the chassis. The drawer having a height dimension, a width dimension, and a length dimension, the enclosure having at least one front portion, a base portion configured to accommodate slack cable disposed within cable channels or cable spools such that the slack cable is routed from a cable inlet along a first side of the draw to a cable outlet disposed along the second side of the drawer. Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

It is to be understood that the disclosure set forth herein includes any possible combinations of the particular features set forth above, whether specifically disclosed herein or not. For example, where a particular feature is disclosed in the context of a particular aspect, embodiment, arrangement, or configuration, that feature can also be used to the extent possible, in combination with and/or in the context of other particular aspects, embodiments, arrangements, and configurations of the technology, and in the technology in general.

Furthermore, although the technology here has been described with reference to particular features and figures, it is to be understood that these features are merely illustrative of the principles and applications of the present technology. It is therefore to be understood that numerous modifications, including changes in the sizes of the various features described herein, may be made to the illustrative arrangement and that other arrangements may be devised without departing from the spirit and scope of the present technology. In this regard, the present technology encompasses numerous additional features in addition to those specific features set forth in the claims below. Moreover, the foregoing disclosure should be taken by way of illustration rather than by way of limitation as the present technology is defined by the claims set forth below.

1. A cable storage panel, comprising:
a drawer having a height dimension, a width dimension, and a length dimension, the drawer having a front portion and a base portion, the base portion having a first row of posts, a second row of posts, and a third row of posts and separator walls defining cable channels configured to accommodate a plurality of slack cable lines; and
a chassis defining an opening that is configured to receive the drawer and two or more cable guides disposed on opposite sides of the opening,
wherein the cable guides are configured to bundle together the plurality of slack cable lines.

2. The panel of claim 1, wherein the first and second rows of posts extend along a first axis and a second axis, respectively, the first and second axes being substantially parallel to each other.

3. The panel of claim 2, wherein the third row of posts extends along a third axis, and wherein the third axis traverses the first and second axes.

4. The panel of claim 2, further comprising a first side post and a second side post disposed proximate a first side of the base portion and a second side of the base portion, respectively.

5. The panel of claim 1, wherein the separator walls are disposed between the first and second rows of posts.

6. The panel of claim 1, wherein one or more posts of the first, second, and third rows of posts have fins extending therefrom.

7. The panel of claim 1, wherein the third row of posts comprises a first non-central post, a central post, and a second non-central post, and wherein the central post is disposed between the first and second non-central posts and proximate to a back portion of the drawer, the back portion being opposite of the front portion.

8. The panel of claim 7, wherein one or more walls of the separator walls extend from at least one of the first non-central post, central post, and/or second non-central post of the third row of posts.

9. The panel of claim 4, further comprising a first side wall and a second side wall.

10. The panel of claim 9, wherein the first and second side walls extend from the first and second side posts, respectively.

11. The panel of claim 10, wherein one or more of the separator walls and/or the first and second side walls defines a curved shape.

12. The panel of claim 10, wherein one or more of the separator walls defines a first radius of curvature and a second radius of curvature.

13. The panel of claim 12, wherein the first radius of curvature and the second radius of curvature combine to form an S-shaped curve.

14. The panel of claim 10, wherein the cable channels are configured to prevent cable lines from crossing over other cable lines within the panel.

15. A cable storage panel, comprising:
a drawer having a front portion, a base portion and a back portion, the front and back portions extending from the base portion, and the base portion including posts and separator walls defining cable channels configured to accommodate a plurality of slack cable lines; and
a chassis including a lid, an opening configured to receive the drawer, and two cable entry points disposed on opposite sides of the opening,
wherein the drawer includes a roller extending from the back portion toward the lid of the chassis.

16. The cable storage panel of claim 15, wherein the roller includes a wheel rotatably attached to the back portion via a bracket.

17. The cable storage panel of claim 16, wherein the bracket includes a slot that allows the wheel to shift toward and away from the lid.

18. The cable storage panel of claim 17, wherein the wheel is spring loaded and configured to press against an inner surface of the lid.

19. The cable storage panel of claim 15, wherein the chassis includes cable straps configured to hold one or more cables together at the two cable entry points.

20. The cable storage panel of claim 15, wherein the cable channels are configured to prevent cable lines from crossing over other cable lines within the panel.
